(19) United States
(12) Patent Application Publication
(10) Pub. No.: US 2004/0261716 A1
(43) Pub. Date: Dec. 30, 2004

(54) Deposition film forming apparatus and deposition film forming method

(75) Inventors: Junichiro Hashizume, Shizuoka (JP); Ryuji Okamura, Shizuoka (JP); Tetsuya Karaki, Shizuoka (JP); Shinji Tsuchida, Shiga (JP); Takashi Ohtsuka, Shizuoka (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/873,209

(22) Filed: Jun. 23, 2004

(30) Foreign Application Priority Data
Jun. 27, 2003 (JP) 2003-184616

(51) Int. Cl. C23C 16/00

(52) U.S. Cl. 118/723 E

(57) ABSTRACT

A deposition film forming apparatus has a reaction vessel the inside of which can be evacuated. In the reaction vessel, a gas supplying unit for supplying a raw material gas is arranged, and a plurality of cylindrical substrates are arranged at equal intervals on a common circumference. A high-frequency electric power introducing unit is arranged outside the reaction vessel. A deposition film is formed on the cylindrical substrates by exciting and dissociating the raw material gas by means of high-frequency electric power. The deposition film forming apparatus has a grounded and conductive cylindrical member placed in an area surrounded by the cylindrical substrates arranged on the common circumference.

### BACKGROUND OF THE INVENTION

1. Field of the Invention

The present invention relates to an apparatus and method of forming a deposition film on a substrate. More specifically, the present invention relates to a deposition film forming apparatus and a deposition film forming method for forming a functional film which is used in fabricating, in particular, a semiconductor device, an electrophotographic photosensitive member, an image input line sensor, an image pickup device, a photovoltaic device, or the like.

2. Related Background Art

A large number of methods using plasma generated by high-frequency electric power, which include a plasma CVD method, an ion plating method, and a plasma etching method, have been conventionally known as deposition film forming methods to be used for forming semiconductor devices, electrophotographic photosensitive members, image input line sensors, image pickup devices, photovoltaic devices, and other various electronics devices and optical devices. Apparatuses used therefor have also been put into practical use.

For example, the plasma CVD method, that is, a method involving decomposing a raw material gas by means of high-frequency glow discharge to form a thin deposition film on a substrate, has been put into practical use as a suitable deposition film forming method. For instance, the method has been used for forming electrophotographic amorphous silicon (hereinafter, amorphous silicon is referred to also as “a-Si”). Various apparatuses for the same purpose have also been proposed.

In particular, the plasma CVD method using VHF band high-frequency electric power (hereinafter, abbreviated as “VHF-PCVD method”) has attracted attention. Various deposition film forming apparatuses each employing the VHF-PCVD method have been actively developed for the following reason. That is, the VHF-PCVD method exhibits a relatively high deposition rate of a deposition film and results in a high-quality deposition film, so the method is expected to achieve both the cost reduction and improvement in the quality of products. Moreover, in particular, the development of a deposition film forming apparatus employing the VHF-PCVD method, which is capable of forming a plurality of a-Si-based electrophotographic photosensitive members at the same time (in other words, capable of providing high productivity), is in progress.

For instance, Japanese Patent Application Laid-Open No. H09-310181 (U.S. Pat. No. 6,145,469) discloses a deposition film forming apparatus, an apparatus in which a reaction vessel is partially constructed of a dielectric member and a plurality of cathode electrodes are arranged outside the reaction vessel to facilitate the generation of homogeneous high-frequency discharge in a large area and to allow uniform and high-speed plasma processing of a large-area substrate.

FIGS. 4A and 4B are schematic structural diagrams each showing an example of such a deposition film forming apparatus. FIG. 4A is a schematic sectional diagram and FIG. 4B is a schematic sectional diagram taken along the line 4B-4B of FIG. 4A.

As shown in the figures, a reaction vessel 201 of this deposition film forming apparatus consists of a cylindrical dielectric member 201(a) and a top cover 201(b). An exhaust pipe 209 is connected to a lower portion of the reaction vessel 201 and the other end of the exhaust pipe 209 is connected to a not-shown exhaust device (such as a vacuum pump). A plurality of cylindrical substrates 205 on which a deposition film is to be formed are arranged on a common circumference in such a way that the substrates surround a central portion of the reaction vessel 201 and their central axis lines are parallel with each other. Each of the cylindrical substrates 205 is held by a substrate support 206 with a built-in substrate heater 207. Gas supplying means 210 is arranged in the reaction vessel 201 and connected to a not-shown gas supplying apparatus with gas cylinders containing SiH₄, GeH₄, H₂, CH₄, B₂H₆, PH₃, Ar, He, or the like. High-frequency electric power introducing means 202 are placed outside the reaction vessel 201. The high-frequency electric power introducing means are connected to a high-frequency electric power supply 203 via a matching box 204 and high-frequency electric power branch means 212. Furthermore, each pair of the substrate support 206 and the cylindrical substrate 205 is made rotatable by a rotation mechanism 208.

The conventional deposition film forming apparatus and method as described above have achieved reduced substrate processing time due to increased film deposition rate, the increased number of substrates that can be processed simultaneously, and improved uniformity and reproducibility of deposition film properties. As a result, an electrophotographic photosensitive member with practical properties and uniformity can be fabricated at low production cost. In addition, in the production, an electrophotographic photosensitive member in which the occurrence of a defect is suppressed to some degree can be fabricated by strictly cleaning the inside of a vacuum reaction vessel.

However, the requisite quality for products employing those deposition films has become higher in the market on a daily basis. In response to such demand, a method and apparatus for forming a deposition film with improved quality have been required.

For example, in color copying machines which have rapidly grown in demand in recent years, the requirements for image defects are more rigorous today than ever before. However, in a product such as an electrophotographic photosensitive member which must have a large-area and relatively thick deposition film, a production process of the photosensitive member takes a long time. Therefore, dust is easily formed during the production process and the probability of the adhesion of dust tends to be higher because the deposition film has a depositional surface with a large area. The adhesion of dust results in the occurrence of abnormal growth of the deposition film. The abnormal growth should be minimized because the abnormal growth directly leads to the occurrence of an image defect in an electrophotographic process using a photosensitive member employing the deposition film.

As described above, problems remain to be solved in order to obtain a deposition film which satisfies the requirements for various optical and electrical properties and which minimizes image defects when used in image formation by an electrophotographic process at a high film deposition rate and in high yield.

The above-described abnormal growth of a deposition film which occurs during the production process of a photosensitive member is as follows.

An a-Si film has the following property. That is, when dust of the order of several micrometers is adhering to the substrate surface, abnormal growth occurs during the film formation with the dust as a core and the so-called “protrusion” grows. The protrusion has a shape of an inverted circular cone with the dust as an origin. A localized level is extremely high at an interface between a normally deposited part and a protrusion part, so that the interface has a low resistance. Consequently, electrified charge passes through the interface to travel toward the substrate. Therefore, a part with a protrusion appears as a white spot on a solid black image formed by an electrophotographic process using a photosensitive member having the a-Si film (appears as a black spot on a solid white image in the case of reverse development). Specifications for the image defect so-called “spot” have become more and more rigorous year after year. A3-sized paper with several spots may be regarded as a faulty copy depending on their sizes. Moreover, the specifications become far more rigorous for a color copying machine. In this case, A3-sized paper with a single spot may be regarded as a faulty copy.

The protrusion results from the dust as a starting point. To prevent the formation of the protrusion, a substrate to be used is washed sufficiently prior to film formation and all the operations involved in a process of installing the substrate in a film forming apparatus are carried out in a clean room or in vacuum. Efforts are being made in this way to minimize the amount of dust adhering to the substrate before the beginning of the film formation. In fact, such efforts have provided some effects.

However, a protrusion also generates owing to another cause in addition to the dust adhering to a substrate before the beginning of film formation. That is, in producing an a-Si photosensitive member, the requisite film thickness is extremely large (specifically, the requisite thickness is in the range of several micrometers to several tens of micrometers). Consequently, the film formation takes several hours to several tens of hours, during which an a-Si film is deposited not only on the substrate but also on the wall of a reactor and a structure in the reactor. Unlike the substrate, the reactor wall and the structure have neither surface nor temperature controlled so that a deposition film is formed satisfactorily. In a certain case, the deposition film deposited on the reactor wall and the structure peels off from them during long hours of film formation owing to its weak adhesion. When such a deposition film peels off during film formation, even if the degree of peeling is slight, it causes dust, which adheres to the photosensitive member surface in the midst of deposition film formation. Then, an abnormal growth occurs from the dust as a starting point, resulting in a protrusion. Therefore, in order to maintain high yield, a substrate prior to film formation must be controlled and, at the same time, the peeling of a film in a film forming vessel during the film formation must be prevented through careful control, which makes it difficult to fabricate an a-Si photosensitive member.

### SUMMARY OF THE INVENTION

The present invention is aimed at providing such a deposition film forming apparatus and a deposition film forming method as described below. The apparatus and the method overcome various problems involved in the conventional deposition film formation as described above, particularly in the fabrication of an electrophotographic photosensitive member. Specifically, the apparatus and the method can prevent the generation of a protrusion and thus the occurrence of an image defect resulting from the protrusion in the electrophotographic photosensitive member, without sacrificing the electrical properties of a deposition film. With the apparatus and the method, stable and high-yield production of the electrophotographic photosensitive member can be performed at relatively low cost, and a deposition film with satisfactory properties can be formed. Therefore, the present invention provides the apparatus and the method capable of producing a high-image-quality and user-friendly electrophotographic photosensitive member employing the deposition film.

More specifically, an object of the present invention is to provide a deposition film forming apparatus for forming a deposition film on a plurality of cylindrical substrates by applying high-frequency electric power to a plurality of high-frequency electric power introducing means to generate glow discharge in a reaction vessel and then by decomposing a raw material gas introduced into the reaction vessel through raw material gas introducing means, the deposition film forming apparatus including: the reaction vessel which can be evacuated and at least a part of which is constructed of a dielectric member; the cylindrical substrates arranged on a common circumference in the reaction vessel; the raw material gas introducing means arranged in the reaction vessel; and the high-frequency electric power introducing means arranged outside the reaction vessel, wherein a conductive and grounded cylindrical member is placed inside a circle defined by the common circumference on which the cylindrical substrates are arranged.

Another object of the present invention is to provide a deposition film forming method including: arranging a plurality of cylindrical substrates on a plurality of substrate holders arranged on a common circumference in a reaction vessel which can be evacuated and at least a part of which is constructed of a dielectric member; applying high-frequency electric power to a plurality of high-frequency electric power introducing means arranged outside the reaction vessel to generate glow discharge in the reaction vessel; and decomposing a raw material gas introduced into the reaction vessel through raw material gas introducing means to form a deposition film on the cylindrical substrates, wherein a conductive cylindrical member is placed inside a circle defined by the common circumference on which the cylindrical substrates are arranged, and the cylindrical member is grounded while forming the deposition film.

### BRIEF DESCRIPTION OF THE DRAWINGS

FIGS. 1A and 1B are schematic structural diagrams each showing a deposition film forming apparatus according to an embodiment of the present invention;

FIG. 2 is a schematic diagram for explaining the definition of an average inclination (θa);

FIGS. 3A, 3B, 3C and 3D are diagrams each showing an example of a layer structure of an electrophotographic photoreceptive member that can be formed by the present invention; and

FIGS. 4A and 4B are schematic structural diagrams each showing an example of an apparatus for producing an electrophotographic photoreceptive member according to a conventional VHF plasma CVD method using a VHF band frequency.

### DESCRIPTION OF THE PREFERRED EMBODIMENTS

Inventors of the present invention have studied intensively to attain the above-described objects, and found that a deposition film forming apparatus and a deposition film forming method allow formation of a deposition film having satisfactory properties on a substrate by providing a plurality of cylindrical substrates arranged at equal intervals on a common circumference and by providing high-frequency electric power introducing means outside a reaction vessel to introduce high-frequency electric power. Further, provision of a grounded, conductive cylindrical member inside an area surrounded by the cylindrical substrates arranged on the common circumference can drastically reduce formation of protrusions, thereby completing the present invention.

According to the present invention, a deposition film having satisfactory properties can be uniformly formed on the substrates with good reproducibility at a high film deposition rate while image defects caused by the protrusions are minimized.

Hereinafter, an embodiment of the present invention exhibiting the above-described effects will be described in more detail.

The inventors of the present invention have studied a method of reducing dust formation due to film peeling by improving adhesion of a deposition film using a deposition film forming apparatus provided with a plurality of cylindrical substrates arranged at equal intervals on a common circumference and with high-frequency electric power introducing means outside a reaction vessel, and have found that a structure around the cylindrical substrates was asymmetric. Asymmetry here roughly refers to asymmetry between the inside and the outside of a circle of the arranged cylindrical substrates, and the adhesion, stress, and the like of the film may be different inside and outside the circle.

A film was formed on the cylindrical substrates at rest and a number distribution of the protrusions was investigated in a circumferential direction of the arranged cylindrical substrates, to determine the effects of the asymmetry. It was found that the protrusions were formed more on the inside than the outside of the circle of the arranged cylindrical substrates, and do not uniformly appear in the circumferential direction. That is, the number of protrusions inside the circle of the arranged cylindrical substrates must be reduced primarily using the deposition film forming apparatus having such a structure to suppress protrusion formation and to reduce image defects to a level which is acceptable even to use in a color copying machine.

The reasons for formation of many protrusions inside the circle of the arranged cylindrical substrates are not yet clarified. However, in the structure of the deposition film forming apparatus, the outside of the circumference lined with the cylindrical substrates faces a furnace wall of the deposition film forming apparatus, whereas the inside thereof does not. Such a difference in spatial structure supposedly causes a difference in film stress of the attached deposition film, thereby affecting adhesion.

On the other hand, a number distribution of the protrusions in the circumferential direction of the arranged cylindrical substrates was investigated for a deposition film forming apparatus further provided with a cylindrical member in a space inside the plurality of cylindrical substrates according to the present invention. A rate of protrusion formation was reduced inside the circle of the arranged cylindrical substrates, and the number distribution of the protrusions was substantially uniform in the circumferential direction. This is probably because the cylindrical member placed in the space inside the circle of the plurality of arranged cylindrical substrates serves as a furnace wall, thereby providing pseudo-symmetry between the inside and the outside of the circle of the arranged cylindrical substrates.

The protrusion reducing effect was most apparent when the distance between the reaction vessel wall and the cylindrical substrates and the distance between the cylindrical substrates and the cylindrical member were substantially the same, using similar dielectric materials for the cylindrical member and the reaction vessel wall. However, the deposition film also adheres to the cylindrical member as a side effect, causing a phenomenon of slightly decreasing the deposition rate of the film deposited on the cylindrical substrates. Thus, inventors of the present invention have further studied a structure collectively providing a protrusion reducing effect and maintenance of the deposition rate.

As a result, the protrusion reducing effect can be maintained while a diameter of the cylindrical member is reduced by changing the material of the cylindrical member from a dielectric material to a conductive material (metal material, for example) and grounding the cylindrical member. On the other hand, the inventors of the present invention have confirmed that the deposition rate is increased significantly by reducing the diameter of the cylindrical member, and reduction of the diameter to a certain degree or smaller can lessen reduction in the deposition rate to a substantially negligible degree.

As described above, adjusting the diameter of the cylindrical member in a specific range is effective for preventing reduction in the deposition rate and providing a sufficient effect of suppressing protrusion formation according to the present invention. That is, the protrusion formation suppressing effect and the maintenance of the deposition rate can be collectively attained by adjusting the diameter of the cylindrical member in the range of 0.10 to 0.80 times, preferably 0.20 to 0.50 times the diameter (that is, the value obtained by subtracting the diameter of the cylindrical substrate from the diameter of a circle connecting central axis lines of the cylindrical substrates) of an inscribed circle coming in contact with each cylindrical substrate within the space surrounded by the cylindrical substrates.

Further, if a cylindrical member is too long, abnormal discharge is easy to cause at its ends, and if too short, the protrusion formation suppressing effect of the present invention is difficult to obtain, and thus, the length of the cylindrical member is an important parameter. Inventors of the present invention have confirmed that according to the present invention, the length of the cylindrical member is optimally adjusted to 0.50 to 0.98 times the height of the reaction vessel of the deposition film forming apparatus.

The present invention has been completed through the above-described studies.

Hereinafter, the deposition film forming apparatus and the deposition film forming method of the present invention will be described in detail with reference to the drawings.

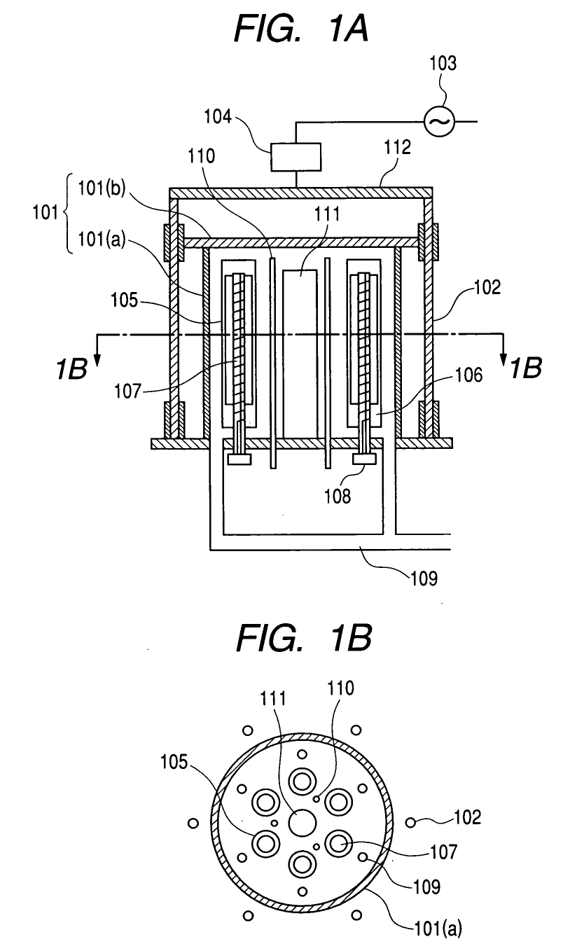

FIGS. 1A and 1B schematically show examples of an apparatus employing the deposition film forming apparatus and the deposition film forming method of the present invention, which is capable of simultaneously forming a plurality of electrophotographic photosensitive members, that is, a plurality of electrophotographic photoreceptive members and is extremely highly productive. FIG. 1A shows a schematic sectional diagram, and FIG. 1B shows a schematic sectional diagram taken along the line 1B-1B of FIG. 1A.

The deposition film forming apparatus shown in FIGS. 1A and 1B are provided with a reaction vessel 101 consisting of a cylindrical dielectric member 101(a) and a top cover 101(b) and the inside of which can be evacuated. A lower portion of the reaction vessel 101 is connected to an exhaust pipe 109, and the other end of the exhaust pipe 109 is connected to a not-shown exhaust device (such as vacuum pump). A plurality of cylindrical substrates 105, on which a deposition film is to be formed, are arranged to surround a central portion of the reaction vessel 101 on a common circumference so that their central axis lines are parallel with each other. The cylindrical substrates 105 are held by respective substrate supports 106 each including a substrate heater 107. Placed inside the reaction vessel 101 are gas supplying means 110 connected to a not-shown gas supplying apparatus equipped with gas cylinders containing SiH₄, GeH₄, H₂, CH₄, B₂H₆, PH₃, Ar, He, or the like. High-frequency electric power introducing means 102 are placed outside the reaction vessel 101. The high-frequency electric power introducing means 102 are connected to a high-frequency electric power supply 103 through a matching box 104 and high-frequency electric power branch means 112. Further, the substrate supports 106, that is, the cylindrical substrates 105 can each rotate by a rotation mechanism 108.

As described above, the deposition film forming apparatus shown in FIGS. 1A and 1B have a structure capable of improving usability of a raw material gas while reducing formation of defects in the deposition film by: restricting the film forming space where the raw material gas is decomposed to a cylindrical area by using the reaction vessel 101; employing a structure in which the central axis of the cylindrical film forming space is aligned with the center of the circle of the arranged cylindrical substrates 105; and providing the high-frequency electric power introducing means 102 outside the circle of the cylindrical substrates 105 to the outside of the reaction vessel 101.

Further, a cylindrical member 111 of a conductive material is placed inside the reaction vessel 101, substantially at the center thereof. Any conductive material can be used as a material for the cylindrical member 111, and a metal material such as aluminum, iron, stainless steel, gold, silver, copper, nickel, chromium, or titanium is preferable in view of easy processing, high durability, and recycle convenience. Further, a composite material or the like composed of two or more types of the materials can also be used suitably.

At least a part of a surface of the cylindrical member 111 preferably has an arithmetical mean roughness (Ra) in the range of 1.0 μm or more to 20 μm or less. Ra of 1.0 μm or more increases a contact area between the surface of the cylindrical member 111 and an a-Si deposition film, resulting in satisfactory adhesion. On the other hand, too large Ra easily take in dust, and the dust expelled may become a cause of protrusion formation. Thus, Ra is preferably adjusted in the range of 1.0 μm or more to 20 μm or less.

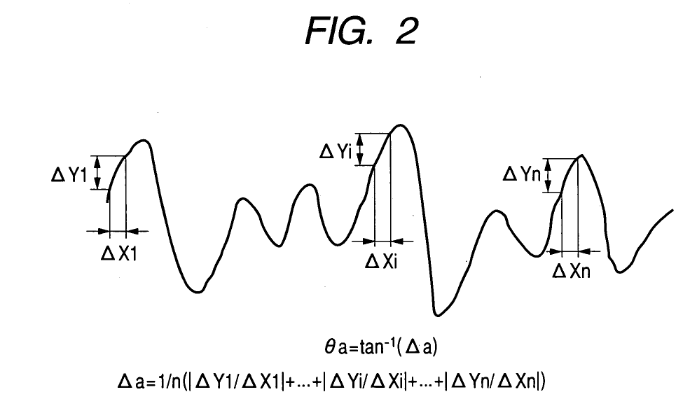

Further, the surface of the cylindrical member 111 preferably has an average inclination (θa) to 9° or more to 20° or less while adjusting Ra within the above range. Here, the average inclination (θa) is, as shown in FIG. 2, represented as an arctangent (74 a=tan⁻¹ Δa) of the average value (Δa) of the sum of the absolute values of local inclinations on a measured curve. θa is an index corresponding to the slope of surface roughness. θa adjusted within the range of 9° to 20° emphasizes the surface irregularities, further improving the adhesion between the surface and the deposition film.

Further, an average spacing (S) between local peaks preferably falls in the range of 30 μm or more to 100 μm or less while Ra is adjusted to be within the above range. S is an index corresponding to the spacing between convex portions of irregularities. S adjusted within the range of 30 to 100 μm also emphasizes the surface irregularities, further improving the adhesion between the surface and the deposition film.

Further, experiments conducted by inventors of the present invention have confirmed that adjusting Ra, θa, and S within the respective ranges described above significantly improves the adhesion between the surface and the deposition film, particularly. Adjusting the Ra, θa, and S within given ranges supposedly results in a more preferable range of the contact area between the cylindrical member 111 and the deposition film, easily alleviating stress of the film deposited on the member and improving adhesion.

The surface roughness according to the embodiment of the present invention was measured according to JIS B0601-1994 and using SURFTEST (SJ-400, manufactured by Mitsutoyo Corporation) at a cut off of 0.8 mm, a reference length of 0.8 mm, and a sampling length of 4 mm.

The surface roughness of the cylindrical member 111 can be controlled within the above range through blast processing or covering with a thermal spraying material. The blast processing or thermal spraying is preferable in view of costs, high controllability of the surface roughness, and not imposing restrictions on the size and shape of a coating target.

Thermal spraying methods are not particularly limited, and the surface of the cylindrical member 111 can be coated through a specific coating method such as plasma spraying, low pressure plasma spraying, high velocity flame spraying, or low temperature spraying. Specific examples of the thermal spraying material include aluminum, nickel, stainless steel, titanium dioxide, and iron. A thickness of the thermal spraying material covering the surface of the cylindrical member 111 is not particularly limited, but is preferably 1 μm to 1 mm, more preferably 10 μm to 500 μm, in view of increasing durability and uniformity and of production costs.

In the deposition film forming apparatus 101 according to the embodiment of the present invention, the cylindrical member 111 must be grounded electrically. The cylindrical member 111 grounded presumably functions as a pseudo-counter electrode to the high-frequency electric power introducing means 102. However, the cylindrical member 111 can sufficiently provide the effect of the present invention by only being grounded, without providing another high-frequency electric power supply for the cylindrical member 111 or branching power from one high-frequency electric power supply 103 into the high-frequency electric power introducing means 102 and the cylindrical member 111 and then making adjustments, for example. That is, the cylindrical member 111 grounded can provide the effect of suppressing protrusion formation without reducing the deposition rate on the cylindrical substrates 105. Thus, the provision of the cylindrical member 111 involves substantially no increase in costs of the deposition film forming apparatus 101 itself and in production costs of the electrophotographic photosensitive member.

According to the present invention, the effect of image defect reduction particularly increases when a frequency of high-frequency electric power for generating glow discharge falls within the range of 50 to 450 MHz. Such enhanced effect supposedly results from the rapid increase of pressure for stable plasma production in a frequency domain lower than 50 MHz. The studies conducted by inventors of the present invention have confirmed that a pressure for stable plasma production at a frequency of 13.56 MHz is about 5 to 10 times as high as the pressure at a frequency of 50 MHz or more. Particles of polysilane or the like are easily formed in a film forming space at such a high pressure, and the particles incorporated in the deposition film easily forms protrusions. On the other hand, the plasma production pressure can be sufficiently suppressed at a frequency of the high-frequency electric power of 50 MHz or more, and thus, a probability of particle formation drastically drops. In this case, the effect of suppressing protrusion formation caused by film peeling can be exhibited according to the present invention, supposedly forming a satisfactory deposition film across the entire circumference of the cylindrical substrates.

Further, the uniformity of the film properties degrades in a frequency domain higher than 450 MHz compared with the domain of 450 MHz or lower. Degradation in the uniformity of the film properties simultaneously causes unevenness in film stress. The film easily peels off in the vicinity of the boundary between areas having a difference in stress, and thus, defects are easily formed in the deposition film. Electric power absorption is large in the vicinity of the power introducing means in a frequency domain higher than 450 MHz, and electrons are produced most frequently here. Thus, plasma tends to be non-uniform, easily causing uneven properties of the deposition film. Extreme electric power absorption hardly occurs in the vicinity of the power introducing means at a frequency of 450 MHz or lower, thereby improving the plasma uniformity and uniformity of film properties.

Further, the high-frequency electric power supply 103 according to the embodiment of the present invention can employ any power supply as long as the power supply is capable of generating high-frequency electric power suitable to the apparatus. Further, output regulation of the high-frequency electric power supply 103 is not particularly limited.

The matching box 104 according to the embodiment of the present invention may have any structure as long as the structure is capable of matching the high-frequency electric power supply 103 with its load. Further, as a matching system, an automatic matching system is suitable for avoiding complication during production, but a manual matching system also has absolutely no influence on the effect of the present invention. Further, the matching box 104 can be placed anywhere in a range of allowing matching, but an arrangement which minimizes an inductance of wiring between the matching box 104 and the high-frequency electric power introducing means 102 is desirable for allowing matching under wide load conditions.

Examples of preferable materials for the high-frequency electric power introducing means 102 and the high-frequency electric power branch means 112 include copper, aluminum, gold, silver, platinum, lead, nickel, cobalt, iron, chromium, molybdenum, titanium, and stainless steel for their good thermal conduction and good electrical conduction. A composite material or the like composed of two or more types of the materials can also be suitably used.

The high-frequency electric power introducing means 102 are preferably arranged at equal intervals on a circle concentric with the circle of the arranged cylindrical substrates 105. The number of the high-frequency electric power introducing means 102 is preferably the same as that of the cylindrical substrates 105 as the example shown in FIG. 1B, but may be half the number of the cylindrical substrates 105. In order to provide the high-frequency electric power introducing means 102 in half the number of the cylindrical substrates 105, each of the high-frequency electric power introducing means 102 is optimally arranged so that the distances with its two adjacent cylindrical substrates 105 are equal. Power can be supplied to the high-frequency electric power introducing means 102 by, for example, supplying power from one high-frequency electric power supply 103 through the matching box 104 and then branching a power supply path by the high-frequency electric power branch means 112. Further examples of power supply include: supplying power from one high-frequency electric power supply 103, branching the power supply path by the high-frequency electric power branch means 112, and then supplying branched power through a plurality of matching boxes; and providing separate high-frequency electric power supplies and matching boxes for the respective high-frequency electric power introducing means 102. However, the power is preferably supplied from one high-frequency electric power supply to all of the high-frequency electric power introducing means 102 in view of completely matching the frequencies of the high-frequency electric power introduced from all of the high-frequency electric power introducing means 102, of apparatus costs, and of apparatus size.

Examples of the high-frequency electric power introducing means 102 include: a rod-like, tubular, spherical or tabular cathode electrode; and means for supplying power from an opening portion provided on an outer conductor of a coaxial structure.

The material for the dielectric member 101(a) of the reaction vessel 101 according to the embodiment of the present invention is preferably a ceramic material, and is preferably a material containing at least one selected from the group specifically consisting of alumina, zirconia, mullite, cordierite, silicon carbide, boron nitride, aluminum nitride, and silicon nitride, for improving the adhesion of the deposition film and effectively preventing the protrusion formation. Of those, alumina, boron nitride, and aluminum nitride are more preferable for excellent electrical properties such as a dielectric dissipation factor and insulation resistance and for small absorbance of high-frequency electric power.

In addition, the shape of an electrophotographic photosensitive member to be fabricated is preferably cylindrical for easy processing, but may be elliptical or polygonal as needed. The shape may be selected according to the member to be fabricated.

At least a part of the surface of the dielectric member 101(a) of the reaction vessel 101 preferably has an arithmetical mean roughness (Ra) in the range of 1 μm or more to 20 μm or less for improving the adhesion of the deposition film and enhancing the effect of suppressing protrusion formation. Further, it is more preferable to adjust the average inclination (θa) in the range of 9° or more to 20° or less while adjusting Ra within the above range or to adjust the average spacing (S) between the local peaks in the range of 30 μm or more to 100 μm or less while adjusting Ra within the above range. Further, adjusting all of the Ra, θa, and S within the respective ranges described above provides particularly significant effect of alleviating image defects.

Examples of preferable materials for the top cover 101(b) of the reaction vessel 101 include copper, aluminum, gold, silver, platinum, lead, nickel, cobalt, iron, chromium, molybdenum, titanium, and stainless steel for their good thermal conduction and good electrical conduction. A composite material or the like composed of two or more types of the materials can also be suitably used.

The material for the cylindrical substrates 105 may be selected according to intended uses of a product, and examples thereof include copper, aluminum, gold, silver, platinum, lead, nickel, cobalt, iron, chromium, molybdenum, titanium, and stainless steel for their good electrical conduction. Further, a composite material or the like composed of two or more types of the materials are also desirable for improving heat resistance.

The substrate heater 107 is only required to be a heating element used in a vacuum. Specific examples thereof include: electrical resistance heating elements such as a sheathed heater, a tabular heater, a ceramic heater, and a carbon heater; thermal radiation lamp heating elements such as a halogen lamp and an infrared lamp; and heating elements as heat exchanging means using a liquid, gas, or the like as a heating medium. Examples of a surface material that can be used for the substrate heater 107 include: metals such as stainless steel, nickel, aluminum, and copper; ceramics; and heat resistant polymer resins.

A deposition film is formed following the procedure schematically described below for example, using the deposition film forming apparatus shown in FIGS. 1A and 1B.

First, the cylindrical substrates 105 held in the respective substrate holders 106 are placed inside the reaction vessel 101, and the inside of the reaction vessel 101 is evacuated through the exhaust pipes 109 using the not-shown exhaust device. Then, the cylindrical substrates 105 are heated and controlled to a given temperature by the heating elements 107.

After the cylindrical substrates 105 reach the given temperature, a raw material gas is introduced into the reaction vessel 101 through the gas supplying means 110. After a flow rate of the raw material gas reaches the set flow rate and a pressure inside the reaction vessel 101 becomes stable, given high-frequency electric power is supplied from the high-frequency electric power supply 103 through the matching box 104 to the high-frequency electric power introducing means 102. Glow discharge is generated inside the reaction vessel 101 by the supplied high-frequency electric power and the raw material gas is excited and dissociated, thereby forming a deposition film on each of the cylindrical substrates 105. Then, after the formation of a deposition film of a desired film thickness, the supply of the high-frequency electric power is stopped and then the supply of the raw material gas is stopped, thereby completing the formation of the deposition film.

The same procedure is repeated several times when forming a deposition film having a multilayer structure. In this case, the discharge is completely stopped once after formation of one layer is completed as described above. Then, the flow rate of the gas and the pressure are changed for a subsequent layer and the discharge is generated again, thereby forming the subsequent layer. Alternatively, after the formation of one layer, the flow rate of the gas, the pressure, and the high-frequency electric power may be gradually changed for the successive layers in a given time period, thereby successively forming a plurality of layers. In this case, a residual gas inside the reaction vessel 101 is preferably sufficiently evacuated every time each of the layers is formed in order to eliminate a fear of contamination due to different gas species used between the layers.

During formation of the deposition film, the cylindrical substrates 105 may be rotated at a given speed by the rotation mechanism 108 as required.

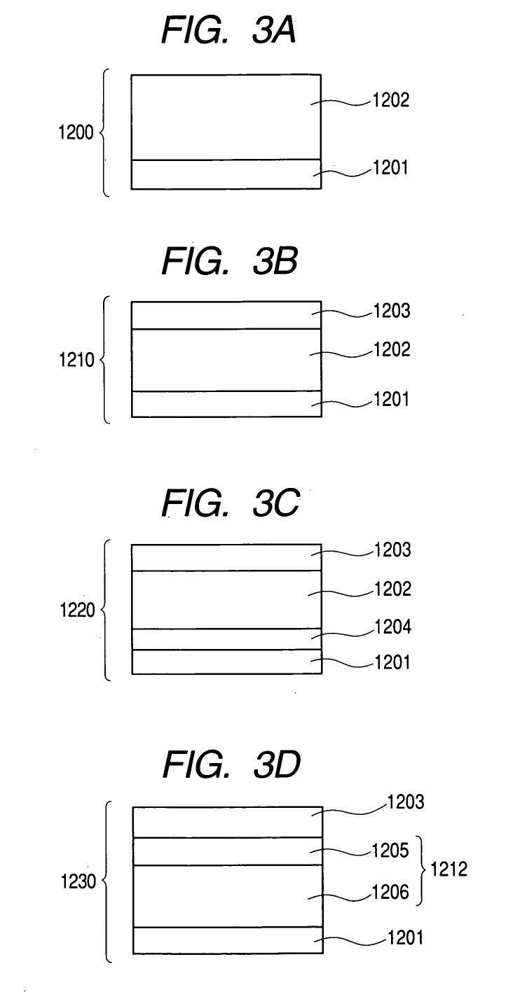

Through the deposition film forming method according to the embodiment of the present invention as described above, a-Si-based electrophotographic photoreceptive members shown in FIGS. 3A to 3D, for example, can be formed.

An electrophotographic photosensitive member 1200 shown in FIG. 3A has a structure provided with, on a support 1201, a photoconductive layer 1202 composed of amorphous silicon containing a hydrogen atom or a halogen atom as a component (hereinafter, referred to also as “a-Si: H, X”) and exhibiting photoconductivity.

An electrophotographic photosensitive member 1210 shown in FIG. 3B has a structure provided with, on the support 1201, the photoconductive layer 1202 composed of a-Si: H, X and exhibiting photoconductivity; and an amorphous silicon-based (or amorphous carbon-based) surface layer 1203.

An electrophotographic photosensitive member 1220 shown in FIG. 3C has a structure provided with, on the support 1201: an amorphous silicon-based charge injection inhibition layer 1204; the photoconductive layer 1202 composed of a-Si: H, X and exhibiting photoconductivity; and the amorphous silicon-based (or amorphous carbon-based) surface layer 1203.

An electrophotographic photosensitive member 1230 shown in FIG. 3D has a structure provided with, on the support 1201: a photoconductive layer 1212 consisting of a charge generation layer 1205 composed of a-Si: H, X and a charge transport layer 1206; and the amorphous silicon-based (or amorphous carbon-based) surface layer 1203 thereon.

### EXAMPLES

Hereinafter, the present invention will be described in more detail with reference to examples, but the present invention is by no means limited to the examples.

### Example 1

An a-Si deposition film was formed on aluminum cylinders each having a diameter of 80 mm and a length of 358 mm as the cylindrical substrates 105 using a deposition film forming apparatus shown in FIGS. 1A and 1B and through the above-described deposition film forming method at an oscillating frequency of the high-frequency electric power supply 103 of 50 MHz under the conditions shown in Table 1, thereby fabricating an electrophotographic photosensitive member.

TABLE 1

| | Charge | | |
|---|---|---|---|
| | injection | | |
| | inhibition | Photoconductive | Surface |
| Item | layer | layer | layer |
| SiH₄ | 300 | 500 | 50 |
| (ml/min (normal)) | | | |
| H₂ | 400 | 400 | 0 |
| (ml/min (normal)) | | | |
| NO | 8 | 0 | 0 |
| (ml/min (normal)) | | | |
| B₂H₆ | 3,000 | 1 | 0 |
| (ppm, based on | | | |
| SiH₄) | | | |
| CH₄ | 0 | 0 | 500 |
| (ml/min (normal)) | | | |
| Power (W) | 500 | 1,000 | 500 |
| Inner pressure | 2.5 | 2.5 | 2.5 |
| (Pa) | | | |
| Film thickness | 2 | 25 | 0.5 |
| (μm) | | | |

The cylindrical member 111 was made of stainless steel and had a diameter 0.30 times the diameter of an inscribed circle in a space surrounded by the cylindrical substrates 105, the inscribed circle coming in contact with each of the cylindrical substrates 105, and a length of 0.80 times the height of the reaction vessel 101. The surface of the cylindrical member 111 had Ra=4.1 μm, θa=14°, and S=50 μm by blast processing.

### Comparative Example 1

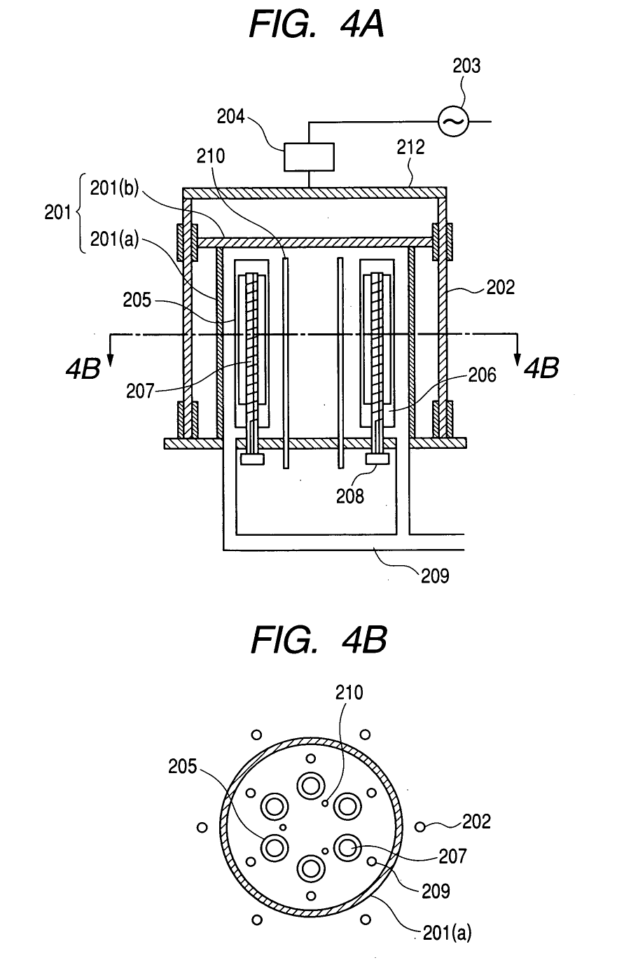

An a-Si photosensitive member was fabricated in the same manner as in Example 1 using a deposition film forming apparatus shown in FIGS. 4A and 4B under the conditions shown in Table 1. Thus, in Comparative Example 1, film formation was conducted under conditions identical to those of Example 1 except that no cylindrical member was used.

Next, the a-Si electrophotographic photosensitive members fabricated in Example 1 and Comparative Example 1 were evaluated as described below.

(Number of Protrusions)

The surfaces of the obtained photosensitive members were observed using an optical microscope. The number of protrusions of 20 μm or larger was counted to determine the number of protrusions per 10 cm².

The obtained results were evaluated based on the following criteria as a relative comparison with the values of Comparative Example 1 defined as 100%.

AA . . . less than 30%

A . . . 30% or more to less than 50%

B . . . 50% or more to less than 70%

C . . . 70% or more to less than 95%

D . . . 95% or more to less than 105%

E . . . increase to 105% or more

(Image Defect)

The electrophotographic photosensitive members fabricated in Example 1 and Comparative Example 1 were installed in a copying machine (iR5000, manufactured by Canon Inc.) remodeled for this test as an electrophotographic apparatus. An A3-size black original was copied under the conditions of a process speed of 265 mm/sec, a pre-exposure of 4 lx·s (an LED having a wavelength of 660 nm), and a current value of a primary charger of 1,0000 μA. The images thus obtained were observed, and the number of white spots having a diameter of 0.3 mm or more caused by the protrusions was counted.

The obtained results were evaluated according to the following criteria as a relative comparison with the values of Comparative Example 1 defined as 100%.

AA . . . less than 30%

A . . . 30% or more to less than 50%

B . . . 50% or more to less than 70%

C . . . 70% or more to less than 95%

D . . . 95% or more to less than 105%

E . . . increase to 105% or more

(Chargeability)

A dark section potential was measured by applying a constant current (1,000 μA, for example) to the primary charger of the electrophotographic apparatus and using a potential sensor of a surface potential meter (Model 344, manufactured by Trek, Inc.) placed at a position of a developing device. Here, a larger dark section potential indicates better chargeability. The chargeability was measured across the entire area in the generating line direction of the photosensitive member, and the average value was regarded as the result. The measurements of the chargeability were evaluated according to the following criteria with respect to the results of Comparative Example 1 as a reference.

AA . . . improvement of 20% or more

A . . . improvement of 15% or more to less than 20%

B . . . improvement of 10% or more to less than 15%

C . . . improvement of 5% or more to less than 10%

D . . . comparable to Comparative Example 1

E . . . degradation

(Sensitivity)

A primary charger current was adjusted so that the dark section potential was kept constant (450 V, for example) at the position of the developing device. Then, sensitivity was evaluated by image exposure, using given white paper having a reflection density of 0.1 or less as an original when the image exposure (semiconductor laser of wavelength 655 nm) was adjusted so that a light section potential at the position of the developing device reached a given value. Here, a smaller image exposure amount indicates better sensitivity. The sensitivity was measured across the entire area in the generating line direction of the photosensitive member, and the average value was regarded as the result. Here, a smaller value indicates a better result. The measurements of the sensitivity were evaluated according to the following criteria with respect to the results of Comparative Example 1 as a reference.

AA . . . improvement of 40% or more

A . . . improvement of 30% or more to less than 40%

B . . . improvement of 20% or more to less than 30%

C . . . improvement of 10% or more to less than 20%

D . . . comparable to Comparative Example 1

E . . . degradation

(Optical Memory)

The current value of the primary charger was adjusted so that the dark section potential reached a given value at the position of the developing device. Then, the image exposure was adjusted so that the light section potential reached a given value, using given white paper as an original. Here, an original prepared by applying black dots of a reflection density of 1.1 and a diameter of 5 mm onto a ghost test chart (made by Canon Inc.) was placed on an original table and a halftone chart (available from Canon Inc.) was piled on the original, thereby obtaining a copy image. A difference in reflection density between the black dots of a diameter of 5 mm on the ghost test chart and a halftone part was measured on a halftone copy image. The optical memory was measured across the entire area in the generating line direction of the photosensitive member, and the average value was regarded as the result. Thus, a smaller value indicates a better result. The measurements of the optical memory were evaluated according to the following criteria with respect to the results of Comparative Example 1 as a reference.

AA . . . improvement of 40% or more

A . . . improvement of 30% or more to less than 40%

B . . . improvement of 20% or more to less than 30%

C . . . improvement of 10% or more to less than 20%

D . . . comparable to Comparative Example 1

E . . . degradation

Table 2 shows the results of the evaluation in Example 1. As being seen from Table 2, the number of protrusions and the image defects reduce significantly by providing the cylindrical member at the center of the area surrounded by the plurality of cylindrical substrates. Further, as an unexpected effect, the electrophotographic photosensitive member in Example 1 was improved in properties such as chargeability, sensitivity, and optical memory as compared with Comparative Example 1.

TABLE 2

| | Example |
|---|---|
| Number of protrusions | AA |
| Image defect | AA |
| Chargeability | B |
| Sensitivity | B |
| Optical memory | B |

### Example 2

An a-Si deposition film was formed on cylindrical aluminum cylinders each having a diameter of 80 mm and a length of 358 mm as the cylindrical substrates 105 using a deposition film forming apparatus shown in FIGS. 1A and 1B and through the above-described deposition film forming method at an oscillating frequency of the high-frequency electric power supply 103 of 105 MHz under the conditions shown in Table 3, thereby fabricating an electrophotographic photosensitive member.

TABLE 3

| | Charge | | |
|---|---|---|---|
| | injection | | |
| | inhibition | Photoconductive | Surface |
| Item | layer | layer | layer |
| SiH₄ | 250 | 250 | 50 |
| (ml/min (normal)) | | | |
| H₂ | 0 | 0 | 0 |
| (ml/min (normal)) | | | |
| NO | 8 | 0 | 0 |
| (ml/min (normal)) | | | |
| B₂H₆ | 1,500 | 2 | 0 |
| (ppm, based on | | | |
| SiH₄) | | | |
| CH₄ | 0 | 0 | 100 |
| (ml/min (normal)) | | | |
| Power (W) | 700 | 2,000 | 1,000 |
| Inner pressure | 6.7 | 6.7 | 6.7 |
| (Pa) | | | |
| Film thickness | 5 | 30 | 0.5 |
| (μm) | | | |

In Example 2, the cylindrical member 111 was made of nickel, and the diameter thereof was changed from 0.05 to 0.85 times the diameter of an inscribed circle in a space surrounded by the cylindrical substrates 105, the inscribed circle inscribing each of the cylindrical substrates 105. The length of the cylindrical member 111 was 0.90 times the height of the reaction vessel 101.

Surface roughness of each cylindrical substrate 105 was adjusted to Ra=6.7 μm, θa=11°, and S=78 μm through thermal spraying of a nickel material.

The electrophotographic photosensitive members obtained through the above-described method were evaluated in the same manner as in Example 1. Further, a deposition rate was evaluated according to the following method.

(Deposition Rate)

The total film thickness at a central portion of the electrophotographic photosensitive member was measured after film formation using an eddy current-type thickness measuring instrument (FISCHERSCOPE MMS, manufactured by Fischer Instruments). Then, the deposition rate was calculated by dividing the measured film thickness by the total time taken to form the film. The deposition rate of the electrophotographic photosensitive member in Comparative Example 1 was defined as 100%, and the results of the evaluation are shown as relative values.

Table 4 shows the results of Example 2. As being seen from Table 4, the number of protrusions and the image defects reduce significantly by providing the cylindrical member having a diameter of 0.10 to 0.80 times the diameter of the inscribed circle in an area surrounded by the cylindrical substrates 105, the inscribed circle coming in contact with each of the cylindrical substrates 105. Further, as the diameter of the cylindrical member decreases within the above range, the deposition rate increases while satisfactory properties are maintained. In particular, the range of 0.50 times or less provides a deposition rate comparable to that of Comparative Example 1, which is especially preferable.

TABLE 4

| | Example 2 | | | | | | | | | |
|---|---|---|---|---|---|---|---|---|---|---|
| | Diameter ratio of | | | | | | | | | |
| | cylindrical member | | | | | | | | | |
| | 0.05 | 0.10 | 0.20 | 0.30 | 0.40 | 0.50 | 0.60 | 0.70 | 0.80 | 0.85 |
| Number of | C | A | AA | AA | AA | AA | AA | AA | A | B |
| protrusions | | | | | | | | | | |
| Image defect | C | A | AA | AA | AA | AA | AA | AA | A | B |
| Chargeability | D | B | B | B | B | B | B | B | B | B |
| Sensitivity | D | B | B | B | B | B | B | B | B | B |
| Optical | D | B | B | B | B | B | B | B | B | B |
| memory | | | | | | | | | | |
| Deposition | 99 | 99 | 99 | 97 | 94 | 90 | 78 | 67 | 55 | 48 |
| rate (%) | | | | | | | | | | |

### Example 3

An a-Si deposition film was formed on aluminum cylinders each having a diameter of 80 mm and a length of 358 mm as the cylindrical substrates 105 using a deposition film forming apparatus shown in FIGS. 1A and 1B and through the above-described deposition film forming method at an oscillating frequency of the high-frequency electric power supply 103 equal to a superimposed frequency of 105 MHz and 60 MHz under the conditions shown in Table 5, thereby fabricating an electrophotographic photosensitive member.

TABLE 5

| | Charge | | |
|---|---|---|---|
| | injection | | |
| | inhibition | Photoconductive | Surface |
| Item | layer | layer | layer |
| SiH₄ | 200 | 200 | 30 |
| (ml/min (normal)) | | | |
| H₂ | 200 | 200 | 0 |
| (ml/min (normal)) | | | |
| NO | 8 | 0 | 0 |
| (ml/min (normal)) | | | |
| B₂H₆ | 2,500 | 2 | 0 |
| (ppm, based on | | | |
| SiH₄) | | | |
| CH₄ | 0 | 0 | 100 |
| (ml/min (normal)) | | | |
| Power | 500/500 | 1,500/1,500 | 1,000/1,000 |
| (105/60 MHz) (W) | | | |
| Inner pressure | 1.3 | 1.3 | 1.3 |
| (Pa) | | | |
| Film thickness | 3 | 25 | 0.8 |
| (μm) | | | |

In Example 3, the cylindrical member 111 was made of aluminum, and the length thereof was changed from 0.45 to 0.99 times the height of the reaction vessel 101. The diameter of the cylindrical member 111 was 0.80 times the diameter of an inscribed circle in the space surrounded by the cylindrical substrates 105, the inscribed circle coming in contact with each of the cylindrical substrates 105. The surface roughness of each cylindrical substrate 105 was adjusted to Ra=6.8 μm, θa=14°, and S=78 μm through thermal spraying of a stainless steel material. The evaluation was conducted in the same manner as in Example 1.

Table 6 shows the results of Example 3. Table 6 shows that the effects of the present invention are clearly exerted by adjusting the length of the cylindrical member 111 to 0.50 to 0.98 times the height of the reaction vessel 101. The reason for slightly poor properties at 0.99 times the height is probably that discharge focused between the cylindrical member 111 and the upper portion of the reaction vessel 101.

TABLE 6

| | Example 3 | | | | | | | | |
|---|---|---|---|---|---|---|---|---|---|
| | Height of cylindrical member | | | | | | | | |
| | 0.45 | 0.50 | 0.60 | 0.70 | 0.80 | 0.90 | 0.95 | 0.98 | 0.99 |
| Number of protrusions | C | A | AA | AA | AA | AA | AA | AA | C |
| Image defect | C | A | AA | AA | AA | AA | AA | AA | C |
| Chargeability | C | B | B | B | B | B | B | B | D |
| Sensitivity | C | B | B | B | B | B | B | B | D |
| Optical memory | C | B | B | B | B | B | B | B | D |

### Example 4

An a-Si deposition film was formed on aluminum cylinders each having a diameter of 80 mm and a length of 358 mm as the cylindrical substrates 105 using a deposition film forming apparatus shown in FIGS. 1A and 1B and through the above-described deposition film forming method under the conditions shown in Table 7 thereby fabricating an electrophotographic photosensitive member. The cylindrical member 111 was made of iron, and the diameter thereof was 0.40 times the diameter of an inscribed circle in the space surrounded by the cylindrical substrates 105, the inscribed circle coming in contact with each of the cylindrical substrates 105. The length of the cylindrical member 111 was 0.85 times the height of the reaction vessel. The surface of the cylindrical member 111 had Ra=2.6 μm, θa=9°, and S=30 μm through blast processing.

In Example 4, an oscillating frequency of the high-frequency electric power supply 103 was changed within the range of 45 MHz to 500 MHz. Not only a single frequency, but also a superimposed frequency was used. The evaluation was conducted in the same manner as in Example 1.

TABLE 7

| | Charge injection | Photoconductive | |
|---|---|---|---|
| Item | inhibition layer | layer | Surface layer |
| SiH₄ | 500 | 500 | 100 |
| (ml/min (normal)) | | | |
| H₂ | 1,000 | 1,000 | 0 |
| (ml/min (normal)) | | | |
| NO | 5 | 0 | 0 |
| (ml/min (normal)) | | | |
| B₂H₆ | 1,000 | 3 | 0 |
| (ppm, based on | | | |
| SiH₄) | | | |
| CH₄ | 0 | 0 | 200 |
| (ml/min (normal)) | | | |
| Power (W) | 1,000 | 2,500 | 1,000 |
| | (500/500 for | (1250/1250 for | (500/500 for |
| | superimposed | superimposed | superimposed |
| | frequency) | frequency) | frequency) |
| Inner pressure | 2 | 2 | 2 |
| (Pa) | | | |
| Film thickness | 5 | 35 | 1 |
| (μm) | | | |

Table 8 shows the results of Example 4. Table 8 shows that the effects of the present invention are more clearly exerted at the single frequency or superimposed frequency by adjusting the frequency of the high-frequency electric power within the range of 50 to 450 MHz.

TABLE 8

| | Example 4 | | | | | | | | |
|---|---|---|---|---|---|---|---|---|---|
| | Oscillating frequency (MHz) | | | | | | | | |
| | Single | | | | | | | Superimposed | |
| | frequency | | | | | | | frequency | |
| | 45 | 50 | 60 | 105 | 250 | 450 | 500 | 60/105 | 200/450 |
| Number of protrusions | B | AA | AA | AA | AA | AA | B | AA | AA |
| Image defect | B | AA | AA | AA | AA | AA | B | AA | AA |
| Chargeability | C | B | B | B | B | B | C | B | B |
| Sensitivity | C | B | B | B | B | B | C | B | B |
| Optical memory | C | B | B | B | B | B | C | B | B |

### Example 5

An a-Si deposition film was formed on aluminum cylinders each having a diameter of 80 mm and a length of 358 mm as the cylindrical substrates 105 using a deposition film forming apparatus shown in FIGS. 1A and 1B and through the above-described deposition film forming method under the conditions shown in Table 7, thereby fabricating an electrophotographic photosensitive member. The cylindrical member 111 was made of stainless steel, and the diameter thereof was 0.50 times the diameter of an inscribed circle in a space surrounded by the cylindrical substrates 105, the inscribed circle coming in contact with each of the cylindrical substrates 105. The length of the cylindrical member 111 was 0.60 times the height of the reaction vessel 101. A superimposed frequency of 100 MHz and 350 MHz was used as an oscillating frequency of the high-frequency electric power supply 103.

In Example 5, the surface of the cylindrical member 111 was subjected to blast processing to variously change the arithmetical mean roughness Ra, the average inclination θa, and the average spacing S between the local peaks. The evaluation was conducted in the same manner as in Example 1.

Table 9 shows the results of Example 5. As being seen from Table 9, the effect of reducing the number of protrusions and the image defects is more clearly exerted by adjusting the surface roughness of the cylindrical member 111 within the ranges of Ra=1.0 to 20.0 μm, θa=9 to 20°, and S=30 to 100 μm.

TABLE 9

| | Example 5 | | | | | | | | | | | | | | |
|---|---|---|---|---|---|---|---|---|---|---|---|---|---|---|---|
| Ra(μm) | 0.5 | 1.0 | 10 | 20 | 25 | 3 | 15 | 7 | 18 | 9 | 3 | 15 | 7 | 18 | 9 |
| θa(°) | 11 | 13 | 15 | 19 | 10 | 5 | 9 | 10 | 20 | 22 | 11 | 13 | 15 | 19 | 10 |
| S(μm) | 55 | 40 | 35 | 95 | 80 | 55 | 40 | 35 | 95 | 80 | 25 | 30 | 60 | 100 | 110 |
| Number of | B | AA | AA | AA | B | B | AA | AA | AA | B | B | AA | AA | AA | B |
| protrusions | | | | | | | | | | | | | | | |
| Image defect | B | AA | AA | AA | B | B | AA | AA | AA | B | B | AA | AA | AA | B |
| Chargeability | B | B | B | B | B | B | B | B | B | B | B | B | B | B | B |
| Sensitivity | B | B | B | B | B | B | B | B | B | B | B | B | B | B | B |
| Optical memory | B | B | B | B | B | B | B | B | B | B | B | B | B | B | B |

### Example 6

An a-Si deposition film was formed on aluminum cylinders each having a diameter of 80 mm and a length of 358 mm as the cylindrical substrates 105 using a deposition film forming apparatus shown in FIGS. 1A and 1B and through the above-described deposition film forming method under the conditions shown in Table 7, thereby fabricating an electrophotographic photosensitive member. The cylindrical member 111 was made of stainless steel, and the diameter thereof was 0.50 times the diameter of an inscribed circle in the space surrounded by the cylindrical substrates 105, the inscribed circle coming in contact with each of the cylindrical substrates 105. The length of the cylindrical member 111 was 0.60 times the height of the reaction vessel 101. A superimposed frequency of 100 MHz and 350 MHz was used as an oscillating frequency of the high-frequency electric power supply 103.

In Example 6, the surface of the cylindrical member 111 was subjected to thermal spraying using 4 types of materials of an aluminum material, a nickel material, a stainless steel material, and a titanium dioxide material, and as in Example 5, the arithmetical mean roughness Ra, the average inclination θa, and the average spacing S between the local peaks were changed for each thermal spraying material.

The evaluation of the electrophotographic photosensitive members thus obtained was conducted in the same manner as in Example 5. The exactly same results as in Table 9 were obtained for any of the aluminum material, the nickel material, the stainless steel material, and the titanium dioxide material. Thus, thermal spraying was found also suitably usable as means of roughening the surface of the cylindrical member 111.

As described above, the deposition film forming apparatus and the deposition film forming method according to the present invention allow formation of a deposition film having satisfactory properties on the substrate by providing a plurality of cylindrical substrates arranged at equal intervals on a common circumference and by providing high-frequency electric power introducing means outside the reaction vessel to introduce high-frequency electric power. Further, the provision of the grounded, conductive cylindrical member inside the area surrounded by the cylindrical substrates arranged on the common circumference can drastically reduce the formation of the protrusions without lowering the electrical properties of the deposition film. At the same time, the reduction of the deposition film formation time and the improvement of the raw material gas usability can also be attained, and thus, the production cost can be reduced.

What is claimed is:

1. A deposition film forming apparatus for forming a deposition film on a plurality of cylindrical substrates by applying high-frequency electric power to a plurality of high-frequency electric power introducing means to generate glow discharge in a reaction vessel and then by decomposing a raw material gas introduced into the reaction vessel through raw material gas introducing means, the deposition film forming apparatus comprising:
the reaction vessel which can be evacuated and at least a part of which is constructed of a dielectric member;
the cylindrical substrates arranged on a common circumference in the reaction vessel;
the raw material gas introducing means arranged in the reaction vessel; and
the high-frequency electric power introducing means arranged outside the reaction vessel, wherein
a conductive and grounded cylindrical member is placed inside a circle defined by the common circumference on which the cylindrical substrates are arranged.

2. A deposition film forming apparatus according to claim 1, wherein the cylindrical member is placed at a center of the circle defined by the common circumference.

3. A deposition film forming apparatus according to claim 1, wherein the cylindrical member has a diameter 0.10 to 0.80 times a diameter of an inscribed circle in a space surrounded by the cylindrical substrates, the inscribed circle coming in contact with each of the cylindrical substrates.

4. A deposition film forming apparatus according to claim 1, wherein the cylindrical member has a length 0.50 to 0.98 times a height of the reaction vessel.

5. A deposition film forming apparatus according to claim 1, wherein at least a part of a surface of the cylindrical member has an arithmetical mean roughness Ra in a range of 1.0 μm or more to 20.0 μm or less, an average inclination θa in a range of 9° or more to 20° or less, and an average spacing S between local peaks in a range of 30 μm or more to 100 μm or less.

6. A deposition film forming apparatus according to claim 5, wherein a surface roughness of the conductive cylindrical member is adjusted through blast processing.

7. A deposition film forming apparatus according to claim 5, wherein a surface roughness of the conductive cylindrical member is adjusted through thermal spraying.

8. A deposition film forming apparatus according to claim 7, wherein a thermal spraying material used in the thermal spraying comprises at least one selected from the group consisting of aluminum, nickel, stainless steel, and titanium dioxide.

9. A deposition film forming apparatus according to claim 1, wherein the high-frequency electric power introducing means are arranged at equal intervals on a circle concentric with the circle defined by the common circumfererence.

10. A deposition film forming apparatus according to claim 1, wherein a frequency of the high-frequency electric power is in a range of 50 to 450 MHz.

11. A deposition film forming apparatus according to claim 1, wherein the deposition film formed on the cylindrical substrates comprises a non-single crystal material using a silicon atom as a base material.

12. A deposition film forming apparatus according to claim 1, wherein the deposition film forming apparatus is used for producing an electrophotographic photosensitive member.

13. A deposition film forming method, comprising:
arranging a plurality of cylindrical substrates on a plurality of substrate holders arranged on a common circumference in a reaction vessel which can be evacuated and at least a part of which is constructed of a dielectric member;
applying high-frequency electric power to a plurality of high-frequency electric power introducing means arranged outside the reaction vessel to generate glow discharge in the reaction vessel; and
decomposing a raw material gas introduced into the reaction vessel through raw material gas introducing means to form a deposition film on the cylindrical substrates, wherein
a conductive cylindrical member is placed inside a circle defined by the common circumference on which the cylindrical substrates are arranged, and the cylindrical member is grounded while forming the deposition film.

14. A deposition film forming method according to 13, wherein the cylindrical member is placed at a center of the circle defined by the common circumference.

15. A deposition film forming method according to claim 13, wherein the cylindrical member has a diameter 0.10 to 0.80 times a diameter of an inscribed circle in a space surrounded by the cylindrical substrates, the inscribed circle coming in contact with each of the cylindrical substrates.

16. A deposition film forming method according to claim 13, wherein the cylindrical member has a length 0.50 to 0.98 times a height of the reaction vessel.

17. A deposition film forming method according to claim 13, wherein at least a part of a surface of the cylindrical member has an arithmetical mean roughness Ra in a range of 1.0 μm or more to 20 μm or less, an average inclination θa in a range of 9° or more to 20° or less, and an average spacing S between local peaks in a range of 30 μm or more to 100 μm or less.

18. A deposition film forming method according to claim 17, wherein a surface roughness of the conductive cylindrical member is adjusted through blast processing.

19. A deposition film forming method according to claim 17, wherein a surface roughness of the conductive cylindrical member is adjusted through thermal spraying.

20. A deposition film forming method according to claim 19, wherein a thermal spraying material used in the thermal spraying comprises at least one selected from the group consisting of aluminum, nickel, stainless steel, and titanium dioxide.

21. A deposition film forming method according to claim 13, wherein the high-frequency electric power is applied through the high-frequency electric power introducing means arranged at equal intervals on a circle concentric with the circle defined by the common circumference.

22. A deposition film forming method according to claim 13, wherein a frequency of the high-frequency electric power is in a range of 50 to 450 MHz.

23. A deposition film forming method according to claim 13, wherein the deposition film formed on the plurality of cylindrical substrates comprises a non-single crystal material using a silicon atom as a base material.

24. A deposition film forming method according to claim 13, wherein the deposition film forming method is used for forming a deposition film for an electrophotographic photosensitive member.
